(19) United States
(12) Patent Application Publication
(10) Pub. No.: US 2023/0255039 A1
(43) Pub. Date: Aug. 10, 2023

(54) LIGHT-EMITTING DEVICE

(71) Applicant: SHARP KABUSHIKI KAISHA, Sakai City, Osaka (JP)

(72) Inventor: TAKAHIRO DOE, Sakai City, Osaka (JP)

(21) Appl. No.: 18/014,286

(22) PCT Filed: Jul. 29, 2020
(86) PCT No.: PCT/JP2020/029081

§ 371 Date: Jan. 3, 2023

(51) Int. Cl. H10K 50/115; H10K 50/13; H10K 50/814; H10K 50/824

(52) U.S. Cl. CPC H10K 50/115; H10K 50/13; H10K 50/814; H10K 50/824

(57) ABSTRACT

A light-emitting device includes: an anode; a cathode; a light-emitting layer provided between the anode and the cathode, and containing a first light-emitting material emitting a first-color light and a second light-emitting material emitting a second-color light greater in peak wavelength than the first-color light, at least one of the first light-emitting material or the second light-emitting material being quantum dots; and a power supply unit controlling a frequency of a voltage to be applied between the anode and the cathode, in accordance with the first-color light and the second-color light.

### TECHNICAL FIELD

The present disclosure relates to a light-emitting device.

### BACKGROUND ART

Patent Document 1 discloses an organic electro-luminescence (EL) element including a light-emitting layer. The light-emitting layer includes such three layers as a sub light-emitting layer emitting a blue light, a sub light-emitting layer emitting a green light, and a sub light-emitting layer emitting a blue light, all of which are stacked on top of another.

### CITATION LIST

### Patent Literature

[Patent Document 1] Japanese Unexamined Patent Application Publication No. 2016-051845

### SUMMARY OF INVENTION

### Technical Problem

As to the organic EL element disclosed in Patent Document 1, three sub light-emitting layers have to be stacked on top of another so that each of the layers emits one of the blue light, green light, and red light. However, in view of reducing production costs, requests are being made for fewer patterning times of the light-emitting layer capable of emitting light in multiple colors. An aspect of the present disclosure is to obtain a light-emitting layer capable of emitting light in multiple colors while the light-emitting layer is patterned fewer times.

### Solution to Problem

A light-emitting device according to an aspect of the present disclosure includes: an anode; a cathode; a light-emitting layer provided between the anode and the cathode, and containing a first light-emitting material emitting a first-color light and a second light-emitting material emitting a second-color light greater in peak wavelength than the first-color light, at least one of the first light-emitting material or the second light-emitting material being quantum dots; and a power supply unit configured to control a frequency of a drive signal to be applied to either the anode or the cathode, in accordance with the first-color light and the second-color light.

### BRIEF DESCRIPTION OF DRAWINGS

FIG. 1 is a plan view of an enlarged portion of a display region in a display device according to an embodiment.

FIG. 2 is a diagram illustrating an example of an equivalent circuit in the display device according to the embodiment.

FIG. 3 is a cross-sectional view of the display device according to the embodiment.

FIG. 4 is a graph illustrating an example of a drive signal to be supplied to a light-emitting element for emitting a blue light according to the embodiment.

FIG. 5 is a graph illustrating an example of a drive signal to be supplied to a light-emitting element for emitting a green light according to the embodiment.

FIG. 6 is a graph illustrating an example of a drive signal to be supplied to a light-emitting element for emitting a red light according to the embodiment.

FIG. 7 is a graph illustrating a drive signal to be applied to a light-emitting element according to the embodiment and an emission luminance of light.

FIG. 8 is a graph showing fluorescence lifetimes of quantum dots according to the embodiment.

FIG. 9 is a graph illustrating a relationship between a voltage of a drive signal to be applied to a light-emitting layer of a light-emitting element according to the embodiment and an emission intensity.

FIG. 10 is a graph showing a relationship between: a color mixture rate of a red light and a green light and a color mixture rate of a green light and a blue light; and a BT2020 coverage, according to this embodiment.

FIG. 11 is a graph showing a coverage with respect to BT2020 according to this embodiment.

FIG. 12 is a graph illustrating a relationship between a frequency of a drive signal to be applied to a light-emitting layer of a light-emitting element according to the embodiment and an emission intensity.

FIG. 13 is a graph showing a relationship between: a color mixture rate of a red light and a green light and a color mixture rate of a green light and a blue light; and a BT2020 coverage, according to this embodiment.

FIG. 14 is a graph showing a coverage with respect to BT2020.

FIG. 15 is a graph showing an example of a drive signal for driving a light-emitting element by a field sequential technique according to a modification of the embodiment.

### DESCRIPTION OF EMBODIMENT

### Embodiment

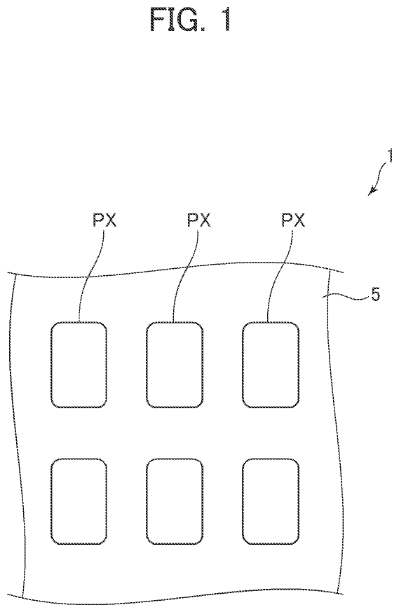

FIG. 1 is a plan view of an enlarged portion of a display region 3 in a display device 1 according to an embodiment. The display device 1 is an example of a light-emitting device according to an aspect of the present disclosure. The display device 1 is, for example, a display. Note that the light-emitting device according to an aspect of the present disclosure shall not be limited to the display device 1. The light-emitting device may be any given device as long as the devise emits light.

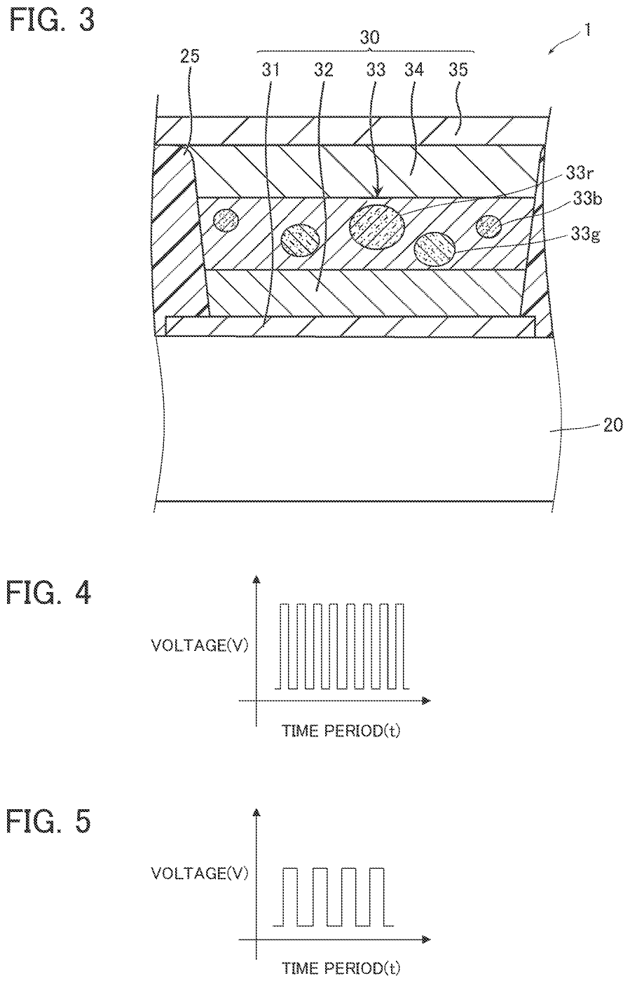

The display device 1 includes, for example, a display region (a display unit) 3 that is a region to display an image, and a frame region (not shown) shaped into a frame and surrounding the display region 3. The display region 3 is provided with a plurality of pixels PX arranged in a matrix. Each of the plurality of pixels PX has a light-emitting element 30 (see FIG. 3). In this embodiment, as will be described later, each pixel PX can emit light in various colors such as red, green, blue or a mixture of these colors.

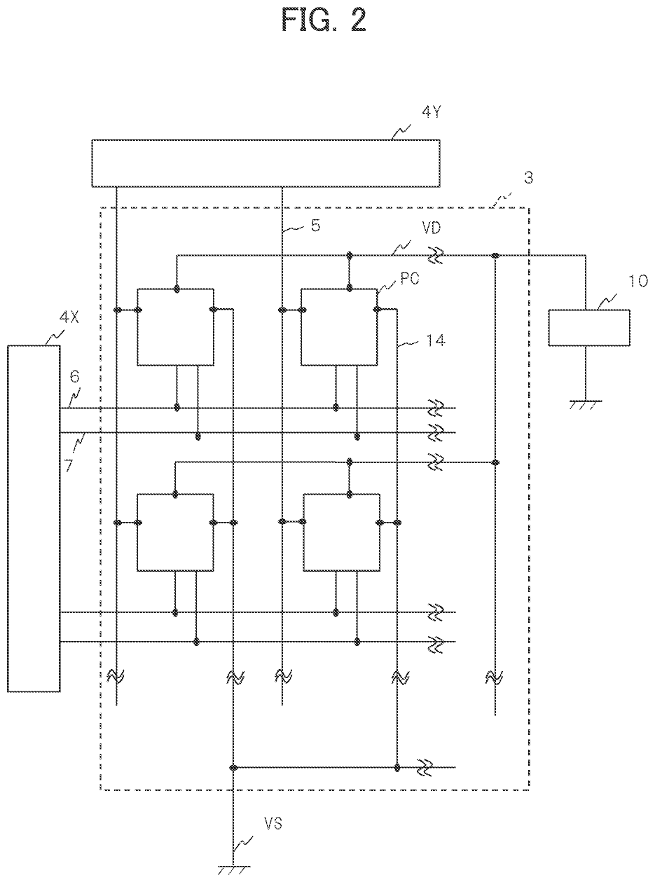

FIG. 2 is a diagram illustrating an example of an equivalent circuit in the display device 1 according to the embodiment. The display device 1 includes, for example, a signal line drive circuit 4Y, a control line drive circuit 4X, a plurality of signal lines 5, a plurality of first control lines 6, a plurality of second control lines 7, a plurality of pixel circuits PC, a first voltage line VD, a second voltage line VS, and a power supply unit 10.

The plurality of signal lines 5 and the plurality of first control lines 6, and the plurality of signal lines 5 and the plurality of second control lines 7, are arranged to intersect with one another in the display region 3. The plurality of the pixel circuits PC are provided, in the display region 3, to the respective intersections of the plurality of signal lines 5 and the plurality of first control lines 6, and to the respective intersections of the plurality of signal lines 5 and the plurality of the second control lines 7.

The signal line drive circuit 4Y and the control line drive circuit 4X cooperate with each other, and drive each of the pixel circuits PC. Each of the pixel circuits PC includes: the light-emitting element 30 (see FIG. 3); and a drive circuit that causes the light-emitting element 30 to emit light.

Each of the plurality of signal lines 5 has one end connected to the signal line drive circuit 4Y. The plurality of signal lines 5 are connected to the pixel circuits PC. The plurality of signal lines 5 receive, from the signal line drive circuit 4Y, a data signal corresponding to an emission luminance for each of the plurality of pixels PX.

Each of the plurality of first and second control lines 6 and 7 has one end connected to the control line drive circuit 4X. The plurality of first and second control lines 6 and 7 are connected to the pixel circuits PC. Each of the plurality of first and second control signal lines 6 and 7 receives, from the control line drive circuit 4X, a control signal for selecting a pixel PX from among the plurality of pixels PX. The pixel PX is selected to emit light.

The power supply unit 10 is connected to the first voltage line VD, and applies ELVDD; namely, a power supply voltage, to the first voltage line VD. Moreover, the power supply unit 10 adjusts the power supply voltage to be applied to the first voltage line VD, in order to control a voltage and a frequency of the drive signal to be supplied to the light-emitting element 30 (see FIG. 3).

The first voltage line VD is connected to each of the pixel circuits PC. The second voltage line VS is connected to each of the pixel circuits PC, and receives ELVSS; namely, a reference voltage. For example, the power supply voltage (ELVDD) is higher than the reference voltage (ELVSS). However, alternatively, the power supply voltage (ELVDD) may be lower than the reference voltage (ELVSS).

FIG. 3 is a cross-sectional view of the display device 1 according to the embodiment. FIG. 3 illustrates an example of a cross-sectional structure of, and around, the light-emitting element 30 in the display device 1. The display device 1 includes: an active substrate 20; the light-emitting element 30 and a bank 25, both of which are provided on the active substrate 20; and a sealing layer that is not shown.

The active substrate 20 includes: a base material; a plurality of thin-film transistors (TFTs) provided above the base material; and various kinds of wires. The base material is made of, for example, either a hard material such as glass or a flexible material. An example of the flexible material includes a resin material such as polyethylene terephthalate (PET) or polyimide.

The bank 25 and the light-emitting element 30 are provided on the active substrate 20. The light-emitting element 30 is capable of emitting light in different colors, depending on a voltage or a frequency of a drive voltage to be applied. For example, the light-emitting element is an organic light-emitting diode (OLED) element, or a quantum-dot light-emitting diode (QLED) element whose light-emitting layer contains a semiconductor nanoparticle material (a quantum-dot material).

The light-emitting element 30 includes, for example, an anode 31, a hole-transport layer 32, a light-emitting layer 33, an electron-transport layer 34, and a cathode 35, all of which are stacked on top of another in the stated order from toward the active substrate 20. For example, the anode 31, the hole-transport layer 32, the light-emitting layer 33, and the electron-transport layer 34 are shaped into islands and provided for each light-emitting element 30. For example, the cathode 35 is provided on the electron-transport layer 34 and the bank 25 continuously throughout the substrate.

The bank 25 covers a peripheral portion (an edge portion) of the anode 31. The bank 25 is provided between neighboring light-emitting elements 30, thereby making it possible to reduce mixture of colors due to leakage of an electric field between the neighboring light-emitting elements 30. That is, the bank 25 functions as an element-separating layer to prevent mixture of colors between the neighboring light-emitting elements 30. For example, the bank 25 is an organic insulating layer made of such an organic material as polyimide resin or acrylic resin.

The bank 25 can be formed, for example, as follows: On the active substrate 20, the anode 31 is patterned in the shape of an island. After that, the hole-transport layer 32, the light-emitting layer 33, and the electron-transport layer 34 are continuously formed for each of the light-emitting elements 30 and etched. A groove portion formed in the etching is filled with an organic material, so that the organic material forms the bank 25. Note that the technique to form the bank 25 shall not be limited to such a technique. Moreover, the display device 1 may omit the bank 25.

The anode 31 is connected to a TFT provided to the active substrate 20. Applied to the anode 31 are a voltage based on an emission luminance of the light-emitting layer 33 and a drive signal having a frequency based on a color of light to be emitted from the light-emitting layer 33. The anode 31 is, for example, a reflective electrode reflective to visible light. The anode 31 has a multilayer structure including: a reflective layer containing, for example, a metal material highly reflective to visible light such as aluminum, copper, gold, or silver; and a transparent layer containing a transparent material such as ITO, IZO, ZnO, AZO, BZO, or GZO. Note that the anode 31 may have a monolayer structure including a reflective layer.

Applied to the cathode 35 is, for example, a reference voltage that is common among the plurality of light-emitting elements 30. The cathode 35 is, for example, a transparent electrode transparent to visible light. The cathode 35 contains, for example, a transparent material such as ITO, IZO, ZnO, AZO, BZO, or GZO.

Note that this embodiment is described on the condition that the power supply unit 10 applies: a reference voltage, which is a constant voltage, to the cathode 35; and a drive signal, which has a relatively high frequency, to the anode 31. The drive signal is applied to each anode 31 shaped into an island. Note that, alternatively, the power supply unit 10 may apply: a drive signal to the cathode 35; and a reference voltage, which is a constant voltage, to the anode 31.

Moreover, this embodiment is described on the condition that the anode 31 is a reflective electrode, and the cathode 35 is a transparent electrode. However, alternatively, the anode 31 may be a transparent electrode and the cathode 35 may be a reflective electrode.

The hole-transport layer 32 is provided between the anode 31 and the light-emitting layer 33. The hole-transport layer 32 transports, for example, charges; namely, holes, to the light-emitting layer 33. In this embodiment, the light-emitting element 30 is driven at a relatively high frequency. Hence, a mobility of the holes in the hole-transport layer 32 is preferably higher than, for example, 4×10⁻³ cm²/Vs. The hole-transport layer 32 preferably contains at least one of, for example, tungsten oxide, nickel oxide, molybdenum oxide, or copper oxide.

Here, compared with an organic material, an inorganic material made of metal oxide is high in charge mobility if the inorganic material is a bulk material. Moreover, the inorganic material can form a film by various film-forming techniques such as using a vacuum apparatus and applying a solution in which particles are dispersed. Hence, the inorganic material is suitable to form a film. Of these film-forming techniques, vacuum vapor deposition using a vacuum apparatus and sputtering provide a metal-oxide thin film with higher crystallizability than coating does. Hence, the vacuum vapor deposition and sputtering can form a thin film having high charge mobility. Meanwhile, when the film is formed by the coating, a thin film with a large area is easily formed, and the coating does not cost much compared with the vacuuming. However, in the thin film formed by the coating, grain boundaries between crystallites limit charge mobility. Hence, the hole-transport layer 32 is preferably a thin film made of an inorganic material containing metal oxide, deposited using a vacuum apparatus, and having high charge mobility. In particular, the hole-transport layer 32 is preferably made of a hole-transport material containing, as a base material, tungsten oxide, molybdenum oxide, or nickel oxide, all of which absorb relatively little light in a wide band gap. The hole-transport material is doped with at least one kind of dissimilar-metal ions selected from Li, Na, K, Mg, and Ca for adjusting a band level and a carrier density.

The electron-transport layer 34 is provided between the cathode 35 and the light-emitting layer 33. The electron-transport layer 34 transports, for example, electrons, to the light-emitting layer 33. In this embodiment, the light-emitting element 30 is driven at a relatively high frequency. Hence, a mobility of the electrons in the electron-transport layer 34 is preferably higher than, for example, 4×10⁻³ cm²/Vs. The electron-transport layer 34 preferably contains either: a material containing at least one of ZnO, TiO₂, or indium gallium zinc oxide (InGaZnO); or the material doped with at least one kind of metal ions selected from Li, Na, K, Mg, and Ca.

For example, the electron-transport layer 34 is made of an electron-transport material containing ZnO, TiO₂, or InGaZnO and having high charge mobility. The electron-transport layer 34 is formed by coating, vapor deposition, sputtering, or the CVD. Moreover, for adjusting a band level and a carrier density, the electron-transport layer 34 contains, more preferably, an electron-transport material doped with dissimilar-metal ions.

Note that, between the anode 31 and the hole-transport layer 32, another layer such as a hole-injection layer may be provided. Furthermore, between the cathode 35 and the electron-transport layer 34, another layer such as an electron-injection layer may be provided.

The light-emitting layer 33 is provided between the anode 31 and the cathode 35. Specifically, in this embodiment, the light-emitting layer 33 is provided between the hole-transport layer 32 and the electron-transport layer 34. The light-emitting layer 33 emits visible light in accordance with, for example, the holes injected from the hole-transport layer 32 and the electrons injected from the electron-transport layer 34. For example, the light-emitting layer 33 emits light in any one of red, green, and blue, or mixture of these colors (e.g., white).

The light-emitting layer 33 contains: a first light-emitting material emitting a first-color light; and a second light-emitting material emitting a second-color light greater in peak wavelength than the first-color light. At least one of the first light-emitting material or the second light-emitting material is quantum dots. Either the first light-emitting material or the second light-emitting material that is not quantum dots is, for example, an organic EL material.

For example, the light-emitting layer 33 contains: a blue light-emitting material (the first light-emitting material) emitting a blue light (the first-color light); a green light-emitting material (the second light-emitting material) emitting a green light (the second-color light) greater in peak wavelength than the blue light; and a red light-emitting material (a third light-emitting material) emitting a red light greater in peak wavelength than the green light.

Note that the red light is light whose peak wavelength is in a wavelength band of, for example, more than 600 nm and 780 nm or less. Moreover, the green light is light whose peak wavelength is in a wavelength band of, for example, more than 500 nm and 600 nm or less. Furthermore, the blue light is light whose peak wavelength is in a wavelength band of, for example, more than 400 nm and 500 nm or less. Note that the colors of light emitted from the light-emitting materials contained in the light-emitting layer 33 shall not be limited to blue, green, and red. The colors may be at least two different colors.

For example, as to the light-emitting layer 33, the blue light-emitting material (the first light-emitting material), the green light-emitting material (the second light-emitting material), and the red light-emitting material (the third light-emitting material) are made of materials that are different in light-emission-fall frequency at which emission of light decreases by driving at high frequency. For example, in this embodiment, as to the light-emission-fall frequency at which light starts to be emitted, the light-emission-fall frequency is higher for the green light-emitting material (the second light-emitting material) than for the red light-emitting material (the third light-emitting material), and the light-emission-fall frequency is higher for the blue light-emitting material (the first light-emitting material) than for the green light-emitting material (the second light-emitting material).

For example, the light-emitting layer 33 is formed on the condition that the blue light-emitting material (the first light-emitting material), the green light-emitting material (the second light-emitting material), and the red light-emitting material (the third light-emitting material) are each made of quantum dots containing the same material. In such a case, the quantum confinement effect: minimizes an average particle size of the quantum dots in the blue light-emitting material so that the blue light-emitting material can emit a blue light; makes the green light-emitting material larger in average particle size of the quantum dots than the blue light-emitting material so that the green light-emitting material can emit a green light; and makes the red light-emitting material larger in average particle size of the quantum dots than the green light-emitting material so that red light-emitting material can emit a red light.

Moreover, among the red light-emitting material, the green light-emitting material, and the blue light-emitting material, as to the light-emission-fall frequency at which emission of light decreases by driving at high frequency, the frequency is higher for the green light-emitting material than for the red light-emitting material, and the frequency is higher for the blue light-emitting material than for the green light-emitting material.

In addition, as to an energy level correlating with a light-emission start voltage at which light starts to be emitted, the energy levels are higher for the green light-emitting material than for the red light-emitting material, and the energy level is higher for the blue light-emitting material than for the green light-emitting material.

The light-emitting layer 33 can be formed of a solution mixture such as toluene containing, for example, the blue light-emitting material, the green light-emitting material, and the red light-emitting material. The light-emitting layer 33 can be formed by coating of the solution mixture. The blue light-emitting material, the green light-emitting material, and the red light-emitting material may be either quantum dots or an organic electro-luminescence (EL) material. The quantum dots may be selected, for example, from such substances as CdS, CdSe, CdTe, ZnS, ZnSe, ZnTe, InN, InP, InAs, InSb, AlP, AlS, AlAs, AlSb, GaN, GaP, GaAs, GaSb, PbS, and PbSe, or from materials made of combinations of these substances. The organic EL material may be, for example, a polymer-based material soluble to a dispersal solvent.

The blue light-emitting material contained in the light-emitting layer 33 is preferably quantum dots with high emission efficiency. In this embodiment, for example, the blue light-emitting material is quantum dots 33b. Each of the quantum dots 33b is preferably in, for example, a so-called core-shell structure including: a core; and a shell provided around the shell. The core-shell structure improves emission efficiency of the cores. Moreover, if the quantum dots 33b are in a core-shell structure, the cores preferably contain either CdSe_{X}S_{1-X} (where 0≤x≤1) or ZnSe_{y}S_{1-y} (where 0<y≤1) both of which have high emission efficiency, and the shells preferably contain at least one of ZnS, SiO₂, or Al₂O₃. In particular, the shells preferably contain ZnS.

The green light-emitting material contained in the light-emitting layer 33 is preferably quantum dots with high emission efficiency. In this embodiment, for example, the green light-emitting material is quantum dots 33g. Each of the quantum dots 33g is preferably in, for example, a so-called core-shell structure including: a core; and a shell provided around the shell. Moreover, if the quantum dots 33g are in a core-shell structure, the cores preferably contain either CdSe_{X}S_{1-X} (where 0≤x≤1) or InP both of which have high emission efficiency, and the shells preferably contain at least one of ZnS, SiO₂, or Al₂O₃. In particular, the shells preferably contain ZnS.

The red light-emitting material contained in the light-emitting layer 33 may be greater in fluorescence lifetime than the blue light-emitting material and the light-emitting material. The red light-emitting material may be either quantum dots or an organic EL material. In this embodiment, for example, the red light-emitting material is quantum dots 33r. Each of the quantum dots 33r is preferably in, for example, a so-called core-shell structure including: a core; and a shell provided around the shell. Moreover, if the quantum dots 33r are in a core-shell structure, the cores preferably contain either CdSe_{X}Te_{1-X} (where 0≤x≤1) or InP both of which have high emission efficiency, and the shells preferably contain at least one of ZnS, SiO₂, or Al₂O₃. In particular, the shells preferably contain ZnS.

The quantum dots 33b, the quantum dots 33g, and the quantum dots 33r contained in the light-emitting layer 33 require different voltages and frequencies to emit light. Hence, as to the display device 1 according to this embodiment, drive signals to be applied to the light-emitting element 30 have the respective voltages and frequencies based on the quantum dots 33b, the quantum dots 33g, and the quantum dots 33r. Such a feature makes it possible to emit light in different colors; that is, single colors such as blue, green, and red.

Note that at least one of the blue light-emitting material, the green light-emitting material, or the red light-emitting material, all of which are contained in the light-emitting layer 33, is quantum dots. A light-emitting material other than the quantum dots may be an organic EL material. The fluorescence lifetime of the quantum dots is of the order of nanoseconds; whereas, the fluorescence lifetime of the organic EL material is of the order of microseconds to milliseconds. Hence, at least one of the blue light-emitting material, the green light-emitting material, or the red light-emitting material (e.g., the blue light-emitting material) contained in the light-emitting layer 33 is the quantum dots 33, and at least one of the others (e.g., the red light-emitting material) is an organic EL material. Such a feature makes it possible to ensure a wide frequency band for a drive signal that has to be applied to the light-emitting layer 33 for emitting each of a blue light, a green light, and a red light. As a result, the light-emitting layer 33 can exhibit an improvement in chromatic purity of a color of light to be emitted.

Moreover, as the quantum dots 33b, 33g, and 33r exemplified in this embodiment, all the three light-emitting materials; namely, the blue light-emitting material, the green light-emitting material, and the red light-emitting material, may be quantum dots. Quantum dots are higher in chromatic purity of a single color than an organic EL material. If all the three light-emitting materials are quantum dots, a BT2020 coverage can be improved, compared with a case where at least one light-emitting element is an organic EL material.

Note that the stacking order of the layers in the light-emitting element 30 shall not be limited to the above order. For example, the anode 31 may be replaced with a cathode, the hole-transport layer 32 may be replaced with an electron-injection layer, the electron-transport layer 34 may be replaced with a hole-injection layer, and the cathode 35 may be replaced with an anode. Moreover, the anode 31 may be a transparent electrode and the cathode 35 may be a reflective electrode.

As can be seen, as to the display device 1 according to this embodiment, the light-emitting layer 33 included in the light-emitting element 30 contains: the quantum dots 33b (the first light-emitting material) emitting a blue light (the first light); the quantum dots 33g (the second light-emitting material) emitting a green light (the second light) greater in peak wavelength than the blue light; and the quantum dot 33r (the third light-emitting material) greater in peak wavelength than the green light. Then, the power supply unit 10 included in the display device 1 controls, for example, a frequency of a drive signal to be applied to the anode 31 in accordance with the blue light, the green light, and the red light to be emitted from the light-emitting layer 33. Thanks to this feature, each of the blue light, the green light, and the red light is obtained, thereby eliminating the need for patterning three light-emitting layers for emitting light in different colors.

That is, as to the display device 1 according to this embodiment, light-emitting layers 33 are formed to contain the same light-emitting material for neighboring light-emitting elements 30. Such a feature eliminates the need for separately coating a light-emitting layer 33 for each of the light-emitting elements 30. Hence, compared with a case where a light-emitting layer is separately coated for each color of light to be emitted, the feature can reduce the production steps of the display device 1. The reduction of the production steps can reduce production costs of the display device 1.

As can be seen, the display device 1 according to this embodiment can be provided with the light-emitting layers 33 containing the same light-emitting material for the neighboring light-emitting elements 30. Hence, each of the light-emitting layers 33 does not have to be patterned in the shape of an island for a corresponding one of the light-emitting elements 30. The light-emitting layers 33 may be formed as a continuous layer in common among the light-emitting elements 30.

Moreover, each of the hole-transport layer 32 and the electron-transport layer 34 does not have to be patterned in the shape of an island for a corresponding one of the light-emitting elements 30. The hole-transport layer 32 and the electron-transport layer 34 may be formed as continuous layers in common among the light-emitting elements 30.

Moreover, in this embodiment, the light-emitting layer 33 contains: the quantum dots 33b (the first light-emitting material) emitting a blue light (the first light); the quantum dots 33g (the second light-emitting material) emitting a green light (the second light) greater in peak wavelength than the blue light; and the quantum dot 33r (the third light-emitting material) greater in peak wavelength than the green light. Alternatively, the light-emitting layer 33 may contain light-emitting materials emitting light in any two of the colors. In such a case, the light-emitting material emitting light in the remaining one color may be contained in a light-emitting layer of a light-emitting element disposed next to the light-emitting element 30 including the light-emitting layer 33.

Described next are frequencies and voltages of drive signals to be applied to the light-emitting layer 33.

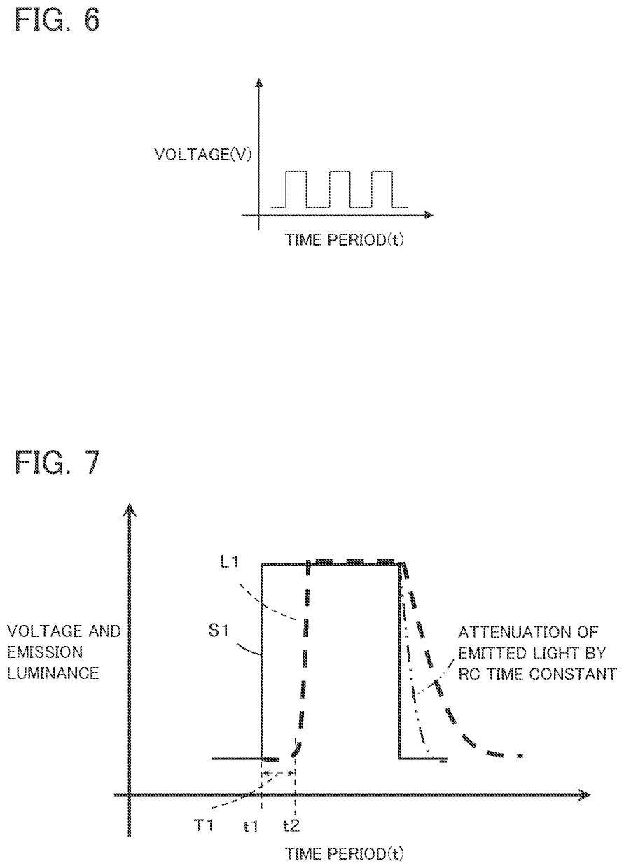

FIG. 4 is a graph illustrating an example of a drive signal to be supplied to a light-emitting element 30 for emitting a blue light according to the embodiment. FIG. 5 is a graph illustrating an example of a drive signal to be supplied to a light-emitting element 30 for emitting a green light according to the embodiment. FIG. 6 is a graph illustrating an example of a drive signal to be supplied to a light-emitting element 30 for emitting a red light according to the embodiment.

For example, the plurality of light-emitting elements 30 in the display device 1 include: a light-emitting element 30 for emitting a blue light; a light-emitting element 30 for emitting a green light; and a light-emitting element 30 for emitting a red light.

FIG. 4 shows that, to the light-emitting element 30 for emitting a blue light, the power supply unit 10 applies a high-voltage square-wave drive signal whose frequency is relatively high. Moreover, FIG. 5 shows that, to the light-emitting element 30 for emitting a green light, the power supply unit 10 applies a square-wave drive signal lower in frequency and voltage than the drive signal to be applied to the light-emitting element 30 for emitting a blue light. Furthermore, FIG. 6 shows that, to the light-emitting element 30 for emitting a red light, the power supply unit 10 applies a square-wave drive signal lower in frequency and voltage than the drive signal to be applied to the light-emitting element 30 for emitting a green light. Note that, to the light-emitting element 30 for emitting a red light, the power supply unit 10 may apply not a square-wave drive signal but a direct-current drive signal.

As can be seen, even if each of the light-emitting layers 33 of the light-emitting elements contains the quantum dots 33b, 33g, and 33r emitting light in multiple colors, a drive signal having a different voltage and a different frequency is applied to each of the light-emitting elements 30 so that a desired color of light can be obtained for each light-emitting element 30. Such a feature will be described below in more detail.

FIG. 7 is a graph illustrating a drive signal to be applied to a light-emitting element 30 according to the embodiment, and an emission luminance of light emitted from a light-emitting material contained in the light-emitting layer 33. A drive signal S1 is a drive signal to be applied to the light-emitting element 30 by the power supply unit 10. When the drive signal S1 having a frequency and a voltage for emitting a blue light, a green light, or a red light is applied to the light-emitting element 30, an emission luminance L1 of the light emitted from the quantum dots 33b, the quantum dots 33g, or the quantum dots 33r in the light-emitting layer 33 varies in accordance with the drive signal S1.

As illustrated in FIG. 7, T1 denotes a light-emission rise time period from a time t1 when the drive signal S1 applied to the light-emitting element 30 rises (a time when the voltage of the drive signal S1 goes from an OFF level to an ON level) to a time t2 when the quantum dots 33b, the quantum dots 33g, or the quantum dots 33r in the light-emitting layer 33 start to emit light.

When the drive signal S1 rises, the emission luminance L1 of the quantum dots 33b, the quantum dots 33g, or the quantum dots 33r in the light-emitting layer 33 also increases. Moreover, when the drive signal S1 falls, the emission luminance of the light emitted from the quantum dots 33b, the quantum dots 33g, or the quantum dots 33r in the light-emitting layer 33 also decreases.

Here, attenuation of light emitted from a light-emitting element is determined by an RC time constant (in proportion to 2πRC) of the light-emitting element, when R (resistance) and C (capacitance) of the light-emitting element are large, However, when a drive signal having a high frequency is applied if the attenuation of the light emitted from the light-emitting element is slow, the emission luminance inevitably rises by the next ON-level drive signal before the emission luminance sufficiently falls. As a result, the light-emitting element might not be able to control the emission luminance as desired.

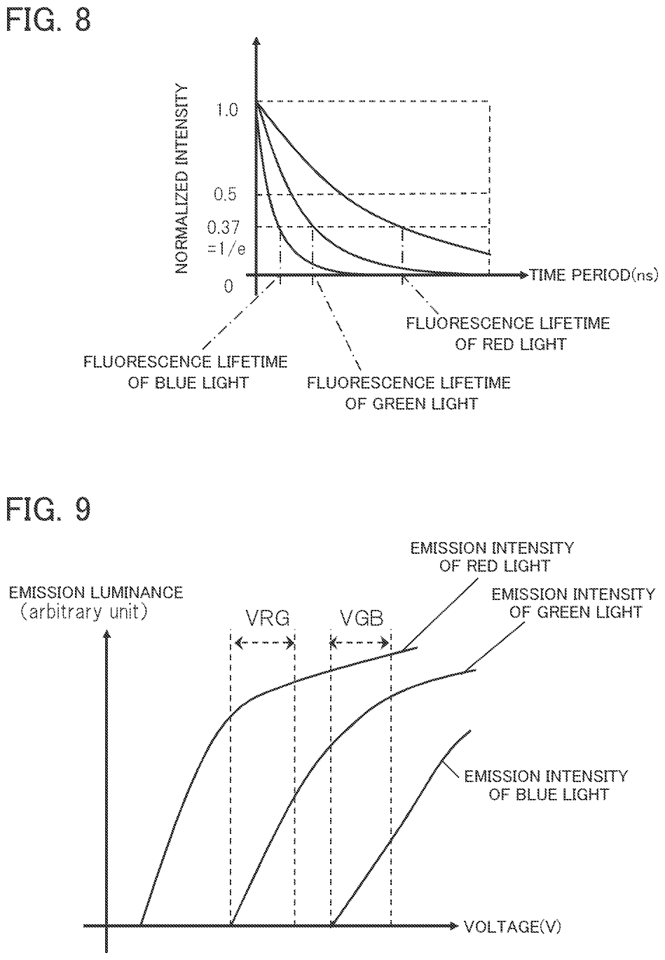

Hence, the light-emitting element 30 according to this embodiment is configured so that R (resistance) and C (capacity) decrease without limit. Thus, attenuation speed of light emitted from the light-emitting element 30 is determined not by the attenuation of light determined by the RC time constant (indicated by the dash-dot-dot-dash line in FIG. 7), but by the fluorescence lifetimes of the quantum dots 33b, the quantum dots 33g, and the quantum dots 33r (to be illustrated later with reference to FIG. 8). Hence, the power supply unit 10 applies, to the light-emitting element 30, a drive signal whose frequency is based on the fluorescence lifetimes of the quantum dots 33b, the quantum dots 33g, and the quantum dots 33r. Such a feature makes it possible to emit light in a desired color out of a blue light, a green light, and a red light.

For example, the light-emission rise time period T1 (FIG. 7) of the quantum dots 33b is preferably shorter than the fluorescence lifetime of the quantum dots 33b. Moreover, for example, the light-emission rise time period T1 (FIG. 7) of the quantum dots 33g is preferably shorter than the fluorescence lifetime of the quantum dots 33g. Furthermore, for example, the light-emission rise time period T1 (FIG. 7) of the quantum dots 33r is preferably shorter than the fluorescence lifetime of the quantum dots 33r. As an example, the light-emission rise time period T1 is preferably shorter than 1 ns.

Such features make it possible to more accurately control colors of light emitted from the light-emitting layer 33 containing the quantum dots 33b, the quantum dots 33g, and the quantum dots 33r, so that the controlled colors are presented as desired.

Moreover, for each of the quantum dots 33b, 33g, and 33r, if the light-emission rise time period T1 is shorter than the fluorescence lifetime, the light-emission rise time period T1 for each of the quantum dots 33b, 33g, and 33r is determined in accordance with a charge mobility of the charges to be injected from the anode 31 and the cathode 35 into the light-emitting layer 33. Furthermore, the light-emission rise time period T1 of each of the quantum dots 33b, 33g, and 33r is determined essentially by a charge mobility of the charges in each of the electron-transport layer 34 and the hole-transport layer 32.

Hence, in this embodiment, the charge mobility of the charges from the anode 31 and the cathode 35 to the light-emitting layer 33 is preferably higher than 10⁻³ cm²/V·s and lower than 10² cm²/V·s. Moreover, in this embodiment, a mobility of the electrons in the electron-transport layer 34 is preferably higher than 4×10⁻³ cm²/Vs. Furthermore, in this embodiment, a mobility of the holes in the hole-transport layer 32 is preferably higher than 4×10⁻³ cm²/Vs. Here, the charge mobility is calculated by electrochemical impedance spectroscopy measurement of either an electron-only device (EOD) in which an electron-transport layer and a light-emitting layer are held in a thin metal film having a small work function such as a thin aluminum film, or a hole-only device (HOD) in which a hole-transport layer is held in a thin metal film having a large work function such as a thin gold film. Moreover, in a case of not a multilayer but a single thin film, it is assumed that movement of the charges is isotropic in the thin film. On this assumption, there are techniques to measure mobility of the charges in a horizontal direction with respect to the substrate. The techniques include measuring field-effect mobility or effective mobility of a prepared thin-film transistor (TFT), and measuring a response time period of laser excitation as to the prepared TFT. These techniques may be used to measure the charge mobility.

Hence, the light-emission rise time period T1 of each of the quantum dots 33b, 33g, and 33r can be made shorter than the fluorescence lifetime of each of the quantum dots 33b, 33g, and 33r. That is, the light-emission rise time period T1 of each of the quantum dots 33b, 33g, and 33r can be reduced sufficiently, and the light-emitting layer 33 can emit light in a desired color at sufficiently high frequency.

That is, as soon as the drive signal goes from the OFF level to the ON level, the emission luminance L1 rises. Such a feature makes it possible to control colors of light emitted from the light-emitting layer 33 containing the quantum dots 33b, the quantum dots 33g, and the quantum dots 33r emitting light in different colors, so that the controlled colors are presented as desired.

Note that, for example, if the light-emitting layer 33 exhibits a charge mobility of 10⁻³ cm²/V·s, the thickness of the light-emitting layer 33 is, for example, 20 nm, and the voltage of the drive signal is, for example, 4 V. Moreover, if each of the electron-transport layer 34 and the hole-transport layer 32 exhibits a charge mobility of 4×10⁻³ cm²/Vs, the thickness of each of the layers is, for example, 40 nm, and the voltage of the drive signal is, for example, 4 V.

FIG. 8 is a graph showing fluorescence lifetimes of the quantum dots 33b, 33g, and 33r. As shown in FIG. 8, a fluorescence lifetime indicates a time constant obtained when liner exponential approximation is performed on an attenuation characteristic of photoluminescence (PL) fluorescence emission of a light-emitting material. That is, the fluorescence lifetime is a time when a normalized intensity of an approximate line is 1/e (=0.37).

In this embodiment, a fluorescence lifetime of the green light emitted from the quantum dots 33g is longer than a fluorescence lifetime of the blue light emitted from the quantum dots 33b. Moreover, a fluorescence lifetime of the red light emitted from the quantum dots 33r is longer than a fluorescence lifetime of the green light emitted from the quantum dots 33g. As can be seen, if R (resistance) and C (capacity) of the light-emitting element 30 are sufficiently small, and if the fluorescence lifetimes are greater than the RC time constant, fall time periods of the emission luminance (emission intensity) for the quantum dots 33b, the quantum dots 33g, and the quantum dots 33r are determined not by the emission attenuation by the RC time constant, but by the fluorescence lifetimes. Note that if the blue light-emitting material, the green light-emitting material, or the red light-emitting material in the light-emitting layer 33 is made not of quantum dots but of an organic light-emitting material, the organic light-emitting material is greater in fluorescence lifetime than the quantum dots by several digits.

Then, the frequency characteristics of the quantum dots 33b, 33g, and 33r are proportional to the reciprocals of the fluorescence lifetimes of the quantum dots 33b, 33g, and 33r. That is, if the fluorescence lifetimes of the quantum dots 33b, 33g, and 33r are greater than the RC time constant of the light-emitting element 30, the fluorescence lifetimes of the quantum dots 33b, 33g, and 33r correlate with the frequency characteristics of the quantum dots 33b, 33g, and 33r. Hence, by changing the frequency of a drive signal to be applied to the light-emitting element 30, a desired color of light can be obtained.

Note that if the characteristic frequency of the light-emitting element 30 is f, f is proportional to the reciprocal of the RC time constant, and is represented as f=½πRC. Note that the time constant and the characteristic frequency define different attenuation rates. The time constant is 1/e=0.37, and the characteristic frequency is −3 db (0.966).

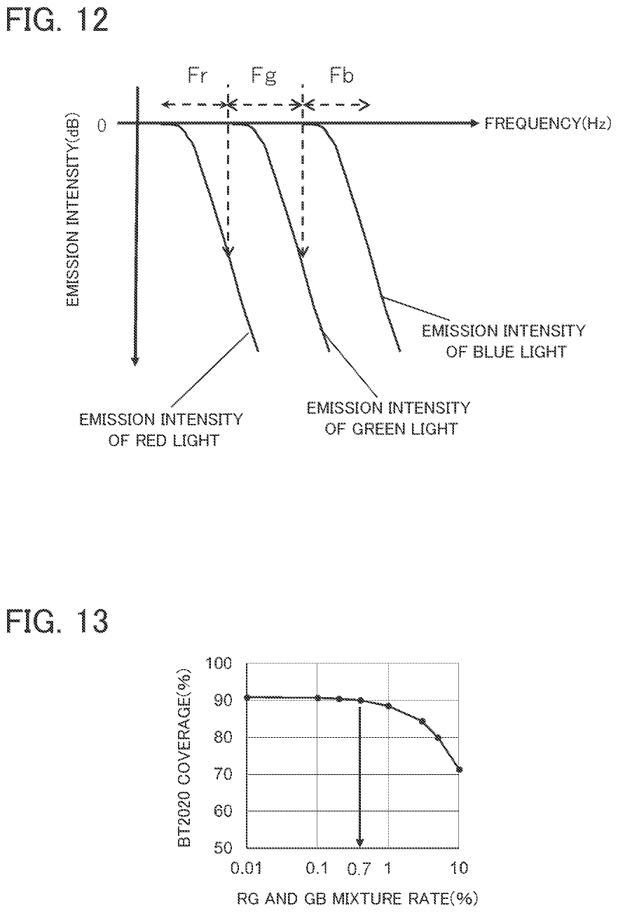

Moreover, details of the frequency characteristics of the quantum dots 33b, 33g, and 33r will be described later, with reference to FIGS. 12 to 14.

Described next with reference to FIGS. 9 to 11 is a relationship between a voltage of a drive signal to be applied to the light-emitting layer 33 and colors of light emitted from the light-emitting layer 33.

FIG. 9 is a graph illustrating a relationship between a voltage of a drive signal to be applied to the light-emitting layer 33 of the light-emitting element 30 according to the embodiment and an emission intensity. In the graph in FIG. 9, the horizontal axis represents the voltage of a drive signal to be applied to the light-emitting layer 33, and the vertical axis represents the emission luminances of the quantum dots 33b, the quantum dots 33g, and the quantum dots 33r contained in the light-emitting layer 33.

FIG. 9 shows that, when the voltage of the drive signal to be applied to the light-emitting layer 33 is raised, the quantum dots 33r start to emit a red light, then, the quantum dots 33g start to emit a green light, and then, the quantum dot 33b start to emit a blue light.

Here, in a voltage range VRG illustrated in FIG. 9, the quantum dots 33g start to emit the green light while the quantum dots 33r are emitting the red light. In such a case, the green light is gradually mixed with the red light having high emission luminance. Moreover, in a voltage range VGB illustrated in FIG. 9, the quantum dots 33b start to emit the blue light while the quantum dots 33g are emitting the green light. In such a case, the blue light is gradually mixed with the green light having high emission luminance.

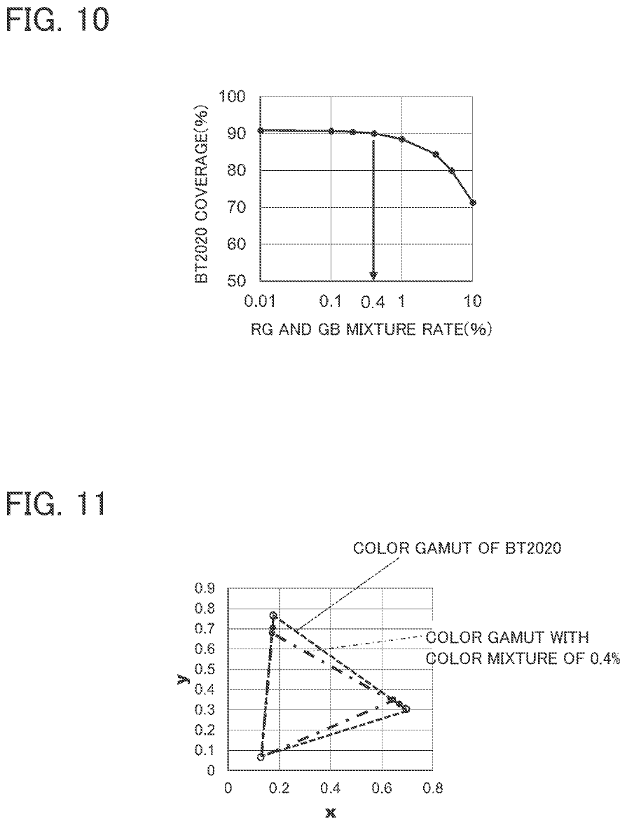

FIG. 10 is a graph showing a relationship between: a color mixture rate of a red light and a green light and a color mixture rate of a green light and a blue light; and a BT2020 coverage, according to this embodiment. FIG. 11 is a graph showing a coverage with respect to BT2020 according to this embodiment. In FIG. 11, the triangle indicated by the broken line represents a color gamut of BT2020. In FIG. 11, the triangle indicated by the dot-and-dash line represents a color gamut observed when the color mixture rate of the green light to the red light and the color mixture rate of the blue light to the green light are 0.4% when converted into energy rates.

As illustrated in FIG. 10, for example, the voltage range of the drive signal to be applied to the light-emitting layer 33 is controlled so that the mixture rate of the green light to the red light and the mixture rate of the blue light to the green light are preferably 0.4% or less when the mixture rates are converted into energy rates. When the mixture rates are converted into luminance rates, the voltage range of the drive signal to be applied to the light-emitting layer 33 is controlled so that the green light has a luminance of preferably 97 cd/m² while the red light has a luminance of 100 cd/m² (G/R=0.97), and the blue light has a luminance of preferably 0.3 cd/m² while the green light has a luminance of 100 cd/m² (B/G=0.003) (i.e. the luminance rates calculated in peak luminosity functions).

Hence, as illustrated in FIGS. 10 and 11, the color gamut of the colors of the light emitted from the light-emitting layer 33 can cover 90% or more of the color gamut of BT2020. That is, the light-emitting element 30 can obtain a large color gamut for the colors of emitted light.

As an example, a direct current or a square wave as the drive signal is assumed to be applied to the light-emitting layer 33. For the drive signal, a voltage for obtaining a red light; namely, a single-color light, ranges 1.7 V or more and less than 4.0 V, a voltage for obtaining a green light; namely, a single-color light, ranges 3.2 V or more and 3.9 V or less, and a voltage for obtaining a blue light; namely, a single-color light, is 4.0 V or more.

Described next with reference to FIGS. 12 to 14 is a relationship between frequencies of a drive signal to be applied to the light-emitting layer 33 and colors of light emitted from the light-emitting layer 33.

FIG. 12 is a graph illustrating a relationship between a frequency of a drive signal to be applied to the light-emitting layer 33 of the light-emitting element 30 according to the embodiment and an emission intensity. In the graph in FIG. 12, the horizontal axis represents a frequency of a drive signal to be applied to the light-emitting layer 33, and the vertical axis represents emission luminances of the quantum dots 33b, the quantum dots 33g, and the quantum dots 33r contained in the light-emitting layer 33.

As can be seen, among the quantum dots 33r, 33g, and 33b contained in the light-emitting layer 33, for example, the quantum dots 33r have the longest fluorescence lifetime, the quantum dots 33g have the second longest fluorescence lifetime next to the quantum dots 33r, and the quantum dots 33b have the third longest fluorescence lifetime next to the quantum dots 33r (i. e. the quantum dots 33b have the shortest fluorescence lifetime). Moreover, as described above, the frequency characteristics of the quantum dots 33b, 33g, and 33r are proportional to the reciprocals of the fluorescence lifetimes of the quantum dots 33b, 33g, and 33r.

As illustrated in FIG. 12, in the light-emitting layer 33, the frequency is raised of the drive signal; that is, a voltage for all the quantum dots 33r, 33g, and 33b to emit light. As the frequency rises, the emission intensity falls (the emitted light attenuates) in the order of the red light, the green light, and the blue light, from a longer to a shorter fluorescence lifetime.

In FIG. 12, a frequency band Fr is a frequency band of a drive signal for obtaining a red light; namely, a single-color light, a frequency band Fg is a frequency band of a drive signal for obtaining a green light; namely, a single-color light, and a frequency band Fb is a frequency band of a drive signal for obtaining a blue light; namely, a single-color light. Of the frequency bands Fr, Fg, and Fb, the frequency band Fr is the lowest, the frequency band Fg is the second lowest next to the frequency band Fr, and the frequency band Fb is the third lowest next to the frequency band Fg (i. e. the frequency band Fb is the highest.)

Here, in a portion of the frequency band Fg to obtain the green light; namely, a single-color light, the red light might mix with the green light depending on the fluorescence lifetime of the quantum dots 33r. Moreover, in a portion of the frequency band Fb to obtain the blue light; namely, a single-color light, the green light might mix with the blue light depending on the fluorescence lifetime of the quantum dots 33g.

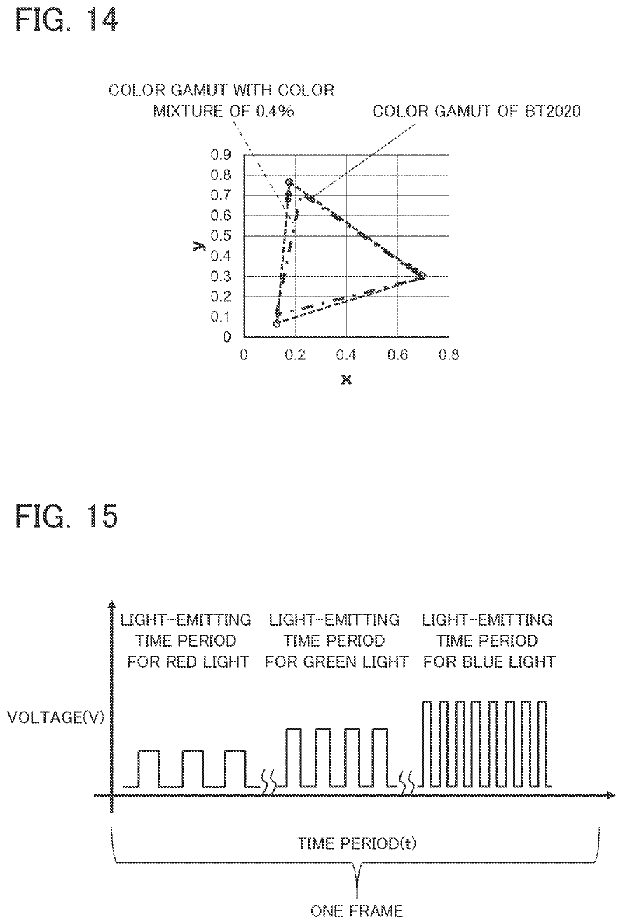

FIG. 13 is a graph showing a relationship between: a color mixture rate of a red light and a green light and a color mixture rate of a green light and a blue light; and a BT2020 coverage, according to this embodiment. FIG. 14 is a graph showing a coverage with respect to BT2020. In FIG. 14, the triangle indicated by the broken line represents a color gamut of BT2020. In FIG. 14, the triangle indicated by the dot-and-dash line represents a color gamut observed when the color mixture rate of the green light to the red light and the color mixture rate of the blue light to the green light are 0.7% when the color mixture rates are converted into energy rates.

As illustrated in FIG. 13, for example, the frequency band of the drive signal to be applied to the light-emitting layer 33 is controlled so that the mixture rate of the red light to the green light and the mixture rate of the green light to the blue light are preferably 0.7% or less when the mixture rates are converted into energy rates. When the mixture rates are converted into luminance rates, the frequency of the drive signal to be applied to the light-emitting layer 33 is controlled so that the red light has a luminance of preferably 0.003 cd/m² while the green light has a luminance of 100 cd/m², and the green light has a luminance of preferably 0.8 cd/m² while the blue light has a luminance of 100 cd/m² (i.e. the luminance rates calculated in peak luminosity functions).

Hence, as illustrated in FIGS. 13 and 14, the color gamut of the colors of the light emitted from the light-emitting layer 33 can cover 90% or more of the color gamut of BT2020. That is, the light-emitting element 30 can obtain a large color gamut for the colors of emitted light.

As an example, as the drive signal, a direct-current drive signal or a square-wave drive signal is assumed to be applied to the light-emitting layer 33. For the drive signal, the frequency band Fr for obtaining a red light; namely, a single-color light, ranges 0 (a direct current) or more and less than 150 kHz, the frequency band Fg for obtaining a green light, a single-color light, ranges 150 kHz or more and less than 140 MHz, and the frequency band Fb for obtaining a blue light, a single-color light, is 140 MHz or more.

As can be seen, for example, the power supply unit 10 applies: as the drive signal to be applied to the light-emitting layer 33, a square wave of 4.0 V or more with a frequency of 140 MHz or more when a blue light is emitted; as the drive signal, a square wave of 3.3 V or more and 3.9 V or less with a frequency of 150 kHz or more and less than 140 MHz when a green light is emitted; and, as the drive signals, a square wave of 1.7 V or more and 4.0 V or less with a frequency of 0 or more and less than 150 kHz when a red light is emitted. Hence, the light-emitting element 30 can obtain a color gamut with a BT2020 coverage of 90% or more.

FIG. 15 is a graph showing an example of a drive signal for driving the light-emitting element 30 by a field sequential technique according to a modification of the embodiment. The display device 1 according to this embodiment may drive the light-emitting element 30 by a field sequential technique (a color-time division technique).

For example, one frame time period for emitting light from one light-emitting element (one pixel PX) is divided into a light-emitting time period for a red light, a light-emitting time period for a green light, and a light-emitting time period for a blue light. In the time period for emitting the red light, a drive signal is applied to the light-emitting element 30 at a frequency and a voltage for emitting the red light. In the time period for emitting the green light, a drive signal is applied to the light-emitting element 30 at a frequency and a voltage for emitting the green light. In the time period for emitting the blue light, a drive signal is applied to the light-emitting element 30 at a frequency and a voltage for emitting the blue light. Hence, the light-emitting element 30 sequentially emits the red light, the green light, and the blue light within one frame time period.

For example, when the display device 1 is driven at a frame rate of 120 Hz (to display a moving picture), one frame time period is approximately 8 ms. Hence, within, for example, approximately 8 ms, the power supply unit 10 sequentially applies, to the light-emitting element 30, the drive signal for emitting the red light, the drive signal for emitting the green light, and the drive signal for emitting the blue light.

Thanks to such a feature, the light-emitting element 30 can emit light in any given color. Here, other than controlling the frequencies and voltages of the drive signals for emitting the red light, the green light, and the blue light, the power supply unit 10 may control a proportion of time lengths per frame time period of the drive signals for emitting the red light, the green light, and the blue light.

Note that, for one frame time period, the drive signals for emitting the red light, the green light, and the blue light may be applied in any given order.

Moreover, the constituent features introduced in the embodiment and the modification described before may be combined as appropriate, as long as the combination does not incur contradiction.

### REFERENCE SIGNS LIST

1 Display Device (Light-Emitting Device), 3 Display Region (Display Unit), 4X Control Line Drive Circuit, 4Y Signal Line Drive Circuit, 5 Signal Line, 6 First Control Line, 7 Second Control Line, 10 Power Supply Unit, 20 Active Substrate, 30 Light-Emitting Element, 31 Anode, 32 Hole-Transport Layer, 33 Light-Emitting Layer, 33b, 33g, 33r Quantum Dots, 34 Electron-Transport Layer, 35 Cathode

1. A light-emitting device, comprising:
an anode;
a cathode;
a light-emitting layer provided between the anode and the cathode, and containing a first light-emitting material emitting a first-color light and a second light-emitting material emitting a second-color light greater in peak wavelength than the first-color light, at least one of the first light-emitting material or the second light-emitting material being quantum dots; and
a power supply unit configured to control a frequency of a drive signal to be applied to either the anode or the cathode, in accordance with the first-color light and the second-color light.

2. The light-emitting device according to claim 1,
wherein the power supply unit applies the drive signal the frequency of which is lower when the second-color light is emitted than when the first-color light is emitted.

3. The light-emitting device according to claim 1,
wherein, in emitting light by either the first light-emitting material or the second light-emitting material that is the quantum dots, a light-emission rise time period is shorter than a fluorescence lifetime, the light-emission rise time period being based on a charge mobility of charges to be injected into the light-emitting layer.

4. The light-emitting device according to claim 3,
wherein the charge mobility is higher than 1×10⁻³ cm²/Vs.

5. The light-emitting device according to claim 3, further comprising
an electron-transport layer provided between the cathode and the light-emitting layer,
wherein, in the electron-transport layer, a mobility of electrons is higher than 4×10⁻³ cm²/Vs.

6. The light-emitting device according to claim 3, further comprising
a hole-transport layer provided between the anode and the light-emitting layer,
wherein, in the hole-transport layer, a mobility of holes is higher than 4×10⁻³ cm²/Vs.

7. The light-emitting device according to claim 5,
wherein the electron-transport layer contains a material containing at least one of ZnO, TiO₂, or InGaZnO.

8. The light-emitting device according to claim 5,
wherein the electron-transport layer contains a material containing at least one of ZnO, TiO₂, or InGaZnO, the material being doped with at least one kind of metal ions selected from Li, Na, K, Mg, and Ca.

9. The light-emitting device according to claim 6,
wherein the hole-transport layer contains either: a material containing at least one of ZnO, TiO₂, or InGaZnO; or the material doped with at least one kind of metal ions selected from Li, Na, K, Mg, and Ca.

10. The light-emitting device according to claim 1,
wherein the light-emitting layer further includes a third light-emitting material emitting a third-color light greater in peak wavelength than the second-color light, and
the power supply unit applies the drive signal the frequency of which is lower when the third-color light is emitted than when the second-color light is emitted.

11. The light-emitting device according to claim 1,
wherein each of the quantum dots includes: a core; and a shell provided around the core, and the shell contains at least one of ZnS, SiO₂, or Al₂O₃.

12. The light-emitting device according to claim 11,
wherein the first-color light is a blue light,
the first light-emitting material is the quantum dots, and
the core contains either CdSe_{X}S_{1-X} (where 0≤x≤1) or ZnSe_{y}S_{1-y} (where 0<y≤1).

13. The light-emitting device according to claim 11,
wherein the second-color light is a green light,
the second light-emitting material is the quantum dots, and
the core contains either CdSe_{X}S_{1-X} (where 0≤x≤1) or InP.

14. The light-emitting device according to claim 10,
wherein the third-color light is a red light, and
the third light-emitting material is quantum dots containing either CdSe_{X}Te_{1-X} (where 0≤x≤1) or InP.

15. The light-emitting device according to claim 10,
wherein the power supply unit applies:
as the drive signal, a square wave of 4.0 V or more with a frequency of 140 MHz or more when the first-color light is emitted;
as the drive signal, a square wave of 3.3 V or more and 3.9 V or less with a frequency of 150 kHz or more and less than 140 MHz when the second-color light is emitted; and
as the drive signal, a square wave of 1.7 V or more and 4.0 V or less with a frequency of 0 or more and less than 150 kHz when the third-color light is emitted.

16. The light-emitting device according to claim 1, further comprising
a display unit provided with a plurality of pixels arranged in a matrix, and configured to display an image,
wherein each of the plurality of pixels has at least one light-emitting element including the anode, the cathode, and the light-emitting layer.
